(19) United States
(12) Patent Application Publication
(10) Pub. No.: US 2013/0027118 A1
(43) Pub. Date: Jan. 31, 2013

(54) CAPACITIVE TOUCH PANEL AND A METHOD OF MANUFACTURING THE SAME

(71) Applicants: KWAN-SIN HO, Miaoli County (TW); Yanjun Xie, Wuhan (CN); Xiaodan Zou, Ji'an (CN)

(72) Inventors: KWAN-SIN HO, Miaoli County (TW); Yanjun Xie, Wuhan (CN); Xiaodan Zou, Ji'an (CN)

(21) Appl. No.: 13/398,845

(22) Filed: Feb. 17, 2012

(30) Foreign Application Priority Data
Jul. 28, 2011 (CN) 201110225214.5

(51) Int. Cl. H03K 17/96; H01H 11/00; H03K 17/975

(52) U.S. Cl. 327/517; 200/600; 29/622

(57) ABSTRACT

The present disclosure relates to structure of a capacitive touch panel and further relates to its manufacturing method. The structure comprises of sensing electrodes and peripheral circuits, wherein each sensing electrode comprises of a plurality of conductive units and a plurality of conductive wires for connecting the conductive units, wherein the conductive wires and peripheral circuits are made of a photosensitive material having an electrically conductive property.

### BACKGROUND

This application claims the benefit of China application No. 201110225214.5, filed on Jul. 28, 2011.

1. Technical Field

The present disclosure relates to a capacitive touch control technology, and more particularly relates to structure of a capacitive touch panel and a method of manufacturing the same.

2. Description of the Related Art

Generally, a touch panel is made by providing a sensing area over a substrate surface, wherein the sensing area senses human fingers or pen-like writing instruments so as to achieve the purpose of touch control. A transparent conductive film (for example, indium tin oxide (ITO) is usually adopted as the material for the sensing area so that the touch control function can be achieved when a user touches and presses the transparent conductive film corresponding to the screen of the display.

Based on the touch control principles, a touch panel can be classified into various types. Among them, capacitive touch panel has advantages in all aspects including transmittance, hardness, accuracy, response time, touch input life, operation temperature, and starting force and therefore has been massively adopted.

FIG. 1 is a schematic diagram showing a conventional capacitive touch panel. The capacitive touch panel 10 comprises a substrate 12, and first sensing electrodes 14 arranged in a first axial direction and second sensing electrodes 16 arranged in a second axial direction on the substrate 12. In FIG. 1, when a user touches the capacitive touch panel 10 with his finger or any other conductive article that is grounded, a touch control spot 18 is formed and a capacitive change occurs at a first sensing electrode 14 and a second sensing electrode 16 that is touched. The system (not shown) then determines location of the touch control spot 18 where the finger touches the capacitive touch panel 10 based on the location on the sensing electrodes where the capacitive change occurs.

It is important to implement the first sensing electrode 14 and the second sensing electrode 16 on the substrate 12 for the making the capacitive touch panel 10. The sensing electrodes are formed usually by covering a conductive film on the substrate 12 and then removing the unwanted areas by a photo-etching process to leave desired patterns.

In a conventional capacitive touch panel, the sensing electrodes are generally made of a metal electrode material or a transparent conductive material (such as ITO). Use of metal electrode material allows the material to be seen by naked eyes and is also liable to be oxidized due to exposure to the atmosphere. When the transparent conductive material is used, even though there is no problem of the material being seen by naked eyes, problem of oxidization still exists. Therefore, irrespective of whether the metal electrode material or the transparent conductive material is used, it is necessary to cover the sensing electrodes with a protective layer, which further increases a step of making the protective layer on the surface of the touch panel.

### SUMMARY

The present disclosure provides a structure of a capacitive touch panel and its manufacturing method, wherein a sensing electrode comprises of conductive units and conductive wires connecting the conductive units, further wherein the conductive wires are made of a photosensitive material having an electrically conductive property. As the photosensitive material with an electrically conductive property has photosensitive property as well as electrically conductive Property at the same time, the conductive wires are not liable to be seen by naked eyes and at the same time provide good electrical connection so that whole appearance of the touch panel can be coordinated. Also, as the photosensitive material having an electrically conductive property is chemically stable, the problem of its being oxidized when exposed to the atmosphere can be improved, and therefore the step of making a protective layer on the surface of the touch panel can be omitted.

The present disclosure provides a structure of a capacitive touch panel comprising: sensing electrodes having a plurality of conductive units and a plurality of conductive wires for connecting the conductive units, characterized in that the conductive wires are made of a photosensitive material having an electrically conductive property.

According to the present disclosure, structure of a capacitive touch panel is characterized in that the photosensitive material having an electrically conductive property is a photosensitive material doped with metal particles.

According to the present disclosure, structure of the capacitive touch panel is characterized in that the metal particles are one or more of gold, silver, copper, iron or aluminum, and any combinations thereof.

According to the present disclosure, structure of the capacitive touch panel is characterized in that the photosensitive material having an electrically conductive property is a photosensitive material doped with carbon particles.

According to the present disclosure, structure of the capacitive touch panel is characterized in that the sensing electrodes include first sensing electrodes arranged in a first axial direction and second sensing electrodes arranged in a second axial direction, and an insulating layer is disposed between the first sensing electrodes and the second sensing electrodes.

According to the present disclosure, structure of the capacitive touch panel is characterized in that each of the first sensing electrodes includes a plurality of first conductive units and a plurality of first conductive wires connecting the first conductive units, and each of the second sensing electrodes includes a plurality of second conductive units and a plurality of second conductive wires connecting the second conductive units.

According to the present disclosure, structure of the capacitive touch panel is characterized in that the insulating layer is an insulating film having a plurality of openings, wherein the first conductive units, the second conductive units, and the first conductive wires are provided on backside of the insulating film, with the openings of the insulating film aligned with the second conductive units, further wherein the second conductive wires are provided on front side of the insulating film and pass through the openings to connect the second conductive units.

According to the present disclosure, structure of the capacitive touch panel is characterized in that the insulating layer includes a plurality of insulating blocks, each of which is disposed between the first conductive wires and the second conductive wires.

According to the present disclosure, structure of the capacitive touch panel is characterized in that the sensing electrodes are connected to peripheral circuits.

According to the present disclosure, structure of the capacitive touch panel is characterized in that the peripheral circuits and the conductive wires are made of same photosensitive material having an electrically conductive property.

According to the present disclosure, structure of the capacitive touch panel is characterized in that the first conductive units, the second conductive units, and the first conductive wires are made of a transparent conductive material.

According to the present disclosure, structure of the capacitive touch panel is characterized in that the insulating layer is made of a transparent insulating material.

The present disclosure provides a method of manufacturing a capacitive touch panel, comprising the following steps:

disposing a plurality of conductive units on a substrate; and

disposing a plurality of conductive wires, which connect the conductive units to form sensing electrodes, wherein the conductive wires are made of a photosensitive material having an electrically conductive property

According to the present disclosure, the method of manufacturing a capacitive touch panel is characterized in that the photosensitive material having an electrically conductive property is a photosensitive material doped with metal particles.

According to the present disclosure, the method of manufacturing a capacitive touch panel is characterized in that the metal particles include one or more of gold, silver, copper, iron or aluminum, and any combinations thereof.

According to the present disclosure, the method of manufacturing a capacitive touch panel is characterized in that the photosensitive material having an electrically conductive property is a photosensitive material doped with carbon particles.

According to the present disclosure, the method of manufacturing a capacitive touch panel is characterized in that the sensing electrodes include first sensing electrodes arranged in a first axial direction and second sensing electrodes arranged in a second axial direction; the method further comprises a step of disposing an insulating layer between the first sensing electrodes and the second sensing electrodes.

According to the present disclosure, the method of manufacturing a capacitive touch panel is characterized in that each of the first sensing electrodes includes a plurality of first conductive units; each of the second sensing electrodes includes a plurality of second conductive units; the conductive wires include a plurality of first conductive wires connecting the first conductive units and a plurality of second conductive wires connecting the second conductive units.

According to the present disclosure, the method of manufacturing a capacitive touch panel is characterized in that the method further comprises the following steps:

simultaneously disposing first conductive units, second conductive units, and first conductive wires on a substrate;

disposing an insulating film having a plurality of openings on surfaces of the first conductive units, the second conductive units, and the first conductive wires, so that the openings are aligned with the second conductive units; and

disposing second conductive wires on surface of the insulating film.

According to the present disclosure, the method of manufacturing a capacitive touch panel is characterized in that the method further comprises the following the steps:

simultaneously disposing first conductive units, second conductive units, and first conductive wires on a substrate;

disposing an insulating block on each surface of the first conductive wire; and

disposing second conductive wires on the surfaces of the insulating blocks.

According to the present disclosure, the method of manufacturing a capacitive touch panel is characterized in that the method further comprises the step of disposing peripheral circuits, which are connected with the sensing electrodes.

According to the present disclosure, the method of manufacturing a capacitive touch panel is characterized in that the step of disposing peripheral circuits and the step of disposing a plurality of conductive wires are conducted simultaneously.

### BRIEF DESCRIPTION OF THE DRAWINGS

FIG. 1 is a schematic diagram showing a conventional capacitive touch panel.

FIG. 2 is a schematic diagram showing structure of the capacitive touch panel according to a first embodiment of the present disclosure.

FIG. 3 is a schematic diagram showing the first step of making the capacitive touch panel according to the first embodiment of the present disclosure.

FIG. 4 is a schematic diagram showing the second step of making the capacitive touch panel according to the first embodiment of the present disclosure.

FIG. 5 is a partially enlarged diagram of the capacitive touch panel according to the first embodiment of the present disclosure after the second step is completed.

FIG. 6 is a schematic diagram showing structure of the capacitive touch panel according to a second embodiment of the present disclosure.

FIG. 7 is a schematic diagram showing the first step of making the capacitive touch panel according to the second embodiment of the present disclosure.

FIG. 8 is a schematic diagram showing the second step of making the capacitive touch panel according to the second embodiment of the present disclosure.

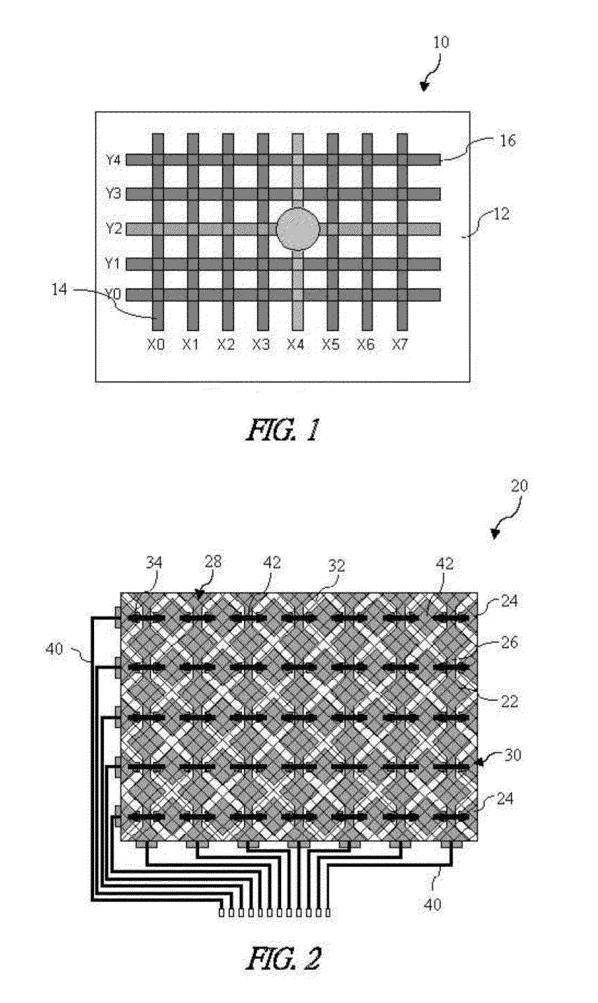

### DETAILED DESCRIPTION OF PREFERRED EMBODIMENTS

Preferred embodiments of the present invention are described below with reference to the drawings.

FIG. 2 is a schematic diagram showing structure of a capacitive touch panel according to a first embodiment of the disclosure. In FIG. 2, the capacitive touch panel 20 comprises of sensing electrodes, an insulating film 32, and peripheral circuits 40.

In an embodiment, the sensing electrodes include first sensing electrodes 28 arranged in a first axial direction and second sensing electrodes 30 arranged in a second axial direction. The first sensing electrodes 28 comprise a plurality of first conductive units 22 and a plurality of first conductive wires 26 connecting the first conductive units 22. The second sensing electrodes 30 comprise a plurality of second conductive units 24 and a plurality of second conductive wires 42 connecting the second conductive units 24.

In another embodiment, peripheral circuits 40 are connected with the first sensing electrodes 28 and the second sensing electrodes 30 such that the capacitive change produced through the first sensing electrodes 28 and the second sensing electrodes 30 due to touching can be transmitted to a control circuit (not shown) by the peripheral circuits 40.

In another embodiment, the first conductive units 22, the second conductive units 24, and the first conductive wires 26 are made of a transparent conductive material. The peripheral circuits 40 and the second conductive wires 42, on the other hand, are made of a photosensitive material having an electrically conductive property. The photosensitive material having an electrically conductive property is a photosensitive material doped with metal particles and/or carbon particles, where the metal particles include gold, silver, copper, iron or aluminum, and any combinations thereof.

Common photosensitive materials (also commonly referred to as photo-resists) are not electrically conductive. According to this embodiment, the photosensitive material having an electrically conductive property is obtained by doping a conventional photosensitive material with electrically conductive metal particles including gold, silver, copper, iron or aluminum, or doping with electrically conductive carbon particles, or any combinations thereof to render the electrically conductive property. Also, as a photosensitive material itself is photosensitive and highly chemically stable, an electrically conductive photosensitive material can be in possession of the electrically conductive property, photosensitivity, and high chemical stability at the same time. When conductive wires or peripheral circuits are made of electrically conductive photosensitive material, a good electrical connection to conductive units can be established to form sensing electrodes. Also, as discussed above, because an additional protective layer is not desired, the problem of conductive wires being liable for oxidation due to exposure to atmosphere can also be solved through the proposed conductive wires.

Furthermore, because a photosensitive material has small thickness, when the photosensitive material having an electrically conductive property is used for making conductive wires or peripheral circuits, the photosensitive material has sheet resistance by means of the aforementioned doping. Sheet resistance is also commonly referred to as surface resistance or film resistance when applied to measurement of films. Sheet resistance has a property of having same measured values irrespective of the size of square. In other words, irrespective of whether the side length is 1 in or 0.1 m, value of sheet resistance is the same. In an embodiment, value of sheet resistance depends on thickness of the photosensitive material having the sheet resistance. Therefore, using a photosensitive material having an electrically conductive property and sheet resistance to make conductive wires or peripheral circuits of a capacitive touch panel as disclosed in the present disclose renders the wires a good electrically conductive property, and also the influences caused by uneven thickness of the conductive wires or peripheral circuits are avoided.

In an embodiment, an insulating film 32 can be used as an insulating layer (represented by cross oblique lines in FIG. 2 to demonstrate that the first sensing electrodes 28 and the second sensing electrodes 30 are covered with the insulating film 32), which is disposed on the first sensing electrodes 28 and the second sensing electrodes 30 and has a plurality of openings 34. Namely, the first conductive units 22, the second conductive units 24, and the first conductive wires 26 are provided on backside of the insulating film 32, with openings 34 of the insulating film 32 aligned with the second conductive units 24. The second conductive wires 42, on the other hand, are provided on front side of the insulating film 32 and pass through the openings 34 to connect the second conductive units 24. The insulating film 32 is made of a transparent insulating material.

A process of manufacturing a capacitive touch panel 20 of the first embodiment is described below with reference to drawings.

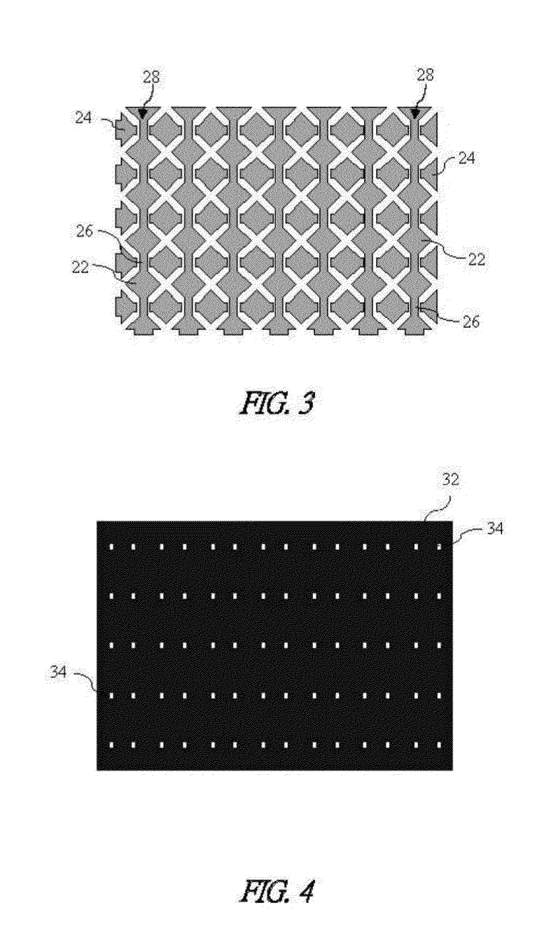

FIG. 3 is a schematic diagram illustrating the first step of making a capacitive touch panel according to the first embodiment of the present disclosure. The first step includes forming on a substrate,(not shown) first conductive units 22 in a first axial direction and second conductive units 24 in a second axial direction, and forming first conductive wires 26 to electrically connect the first conductive units 22 with each other to form a first electrode 28.

FIG. 4 is a schematic diagram illustrating the second step of making the capacitive touch panel according to the first embodiment of the present disclosure. The second step includes etching an insulating film 32 to form a plurality of openings 34 and using the insulating film 32 as an insulating layer to cover the first conductive units 22, the second conductive units 24, and the first conductive wires 26 shown in FIG. 3, wherein the openings 34 of the insulating film 32 are located at the second conductive units 24.

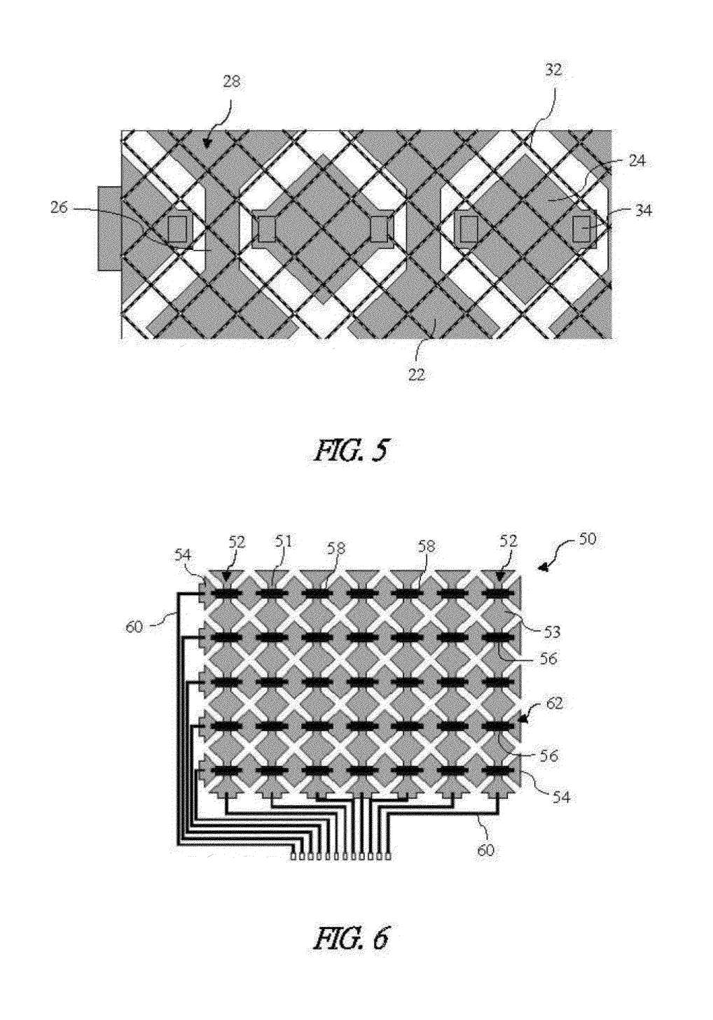

FIG. 5 is a partially enlarged diagram of the capacitive touch panel according to the first embodiment of the present invention after the second step is completed. As the insulating film 32 (represented by cross oblique lines in FIG. 5 to show that the first sensing electrodes 28 and the second sensing electrodes 30 are covered with the insulating film 32) covers most of the sensing electrodes (the first conductive units 22, the first conductive wires 26, and the second conductive units 24, expect for the second conductive units 24 exposed through the openings 34 of the insulating film 32), it can protect the sensing electrodes.

The third step includes using the second conductive wires 42 to electrically connect each of the second conductive units 24 at the openings 34 of the insulating film 32 such that the second conductive units 24 are connected with each other by the second conductive wires 42 to form the second electrodes 30. Also, each peripheral circuit 40 disposed on the substrate (not shown) is electrically connected with the first sensing electrodes 28 and the second sensing electrodes 30. After the aforementioned three steps are completed, structure of capacitive touch panel 20 as shown in FIG. 2 can be obtained.

Therefore, after the aforementioned three steps of making the peripheral circuits 40 and making the second conductive wires 42 with photosensitive material having an electrically conductive property are completed, the conductive wires of the capacitive touch panel 20 of this embodiment would not be easily seen by naked eyes while providing a good electrical connection due to the aforementioned properties of the photosensitive material and therefore the whole appearance of the touch panel can be coordinated. Also, the problem of the second conductive wires 42 and the peripheral circuits 40 being oxidized when exposed to the atmosphere would be substantially unproved due to their good chemical stability. Therefore, the step of making a protective layer on the surface of the touch panel can be omitted.

FIG. 6 is a schematic diagram showing structure of a capacitive touch panel according to a second embodiment of the present disclosure. In FIG. 6, difference in structure of the capacitive touch panel 50 of the second embodiment from the structure of the capacitive touch panel 20 of the first embodiment is that the capacitive touch panel 50 of the second embodiment does not have an insulating film 32, which was present in the capacitive touch panel 20 of the first embodiment. In the capacitive touch panel 50 of the second embodiment, each insulating block 56 acts as an insulating layer that is disposed between the first conductive wires 51 and the second conductive wires 58.

Structure of the capacitive touch panel 50 of the second embodiment is similar to structure of the capacitive touch panel 20 of the first embodiment and therefore description of the same is omitted herein and will be given later.

Process of manufacturing a capacitive touch panel 50 of the second embodiment is described below with reference to the drawings.

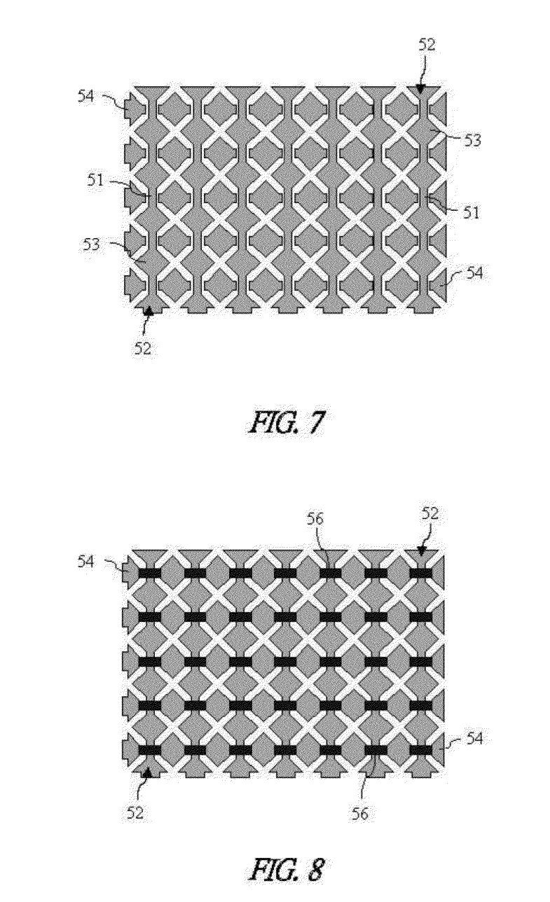

FIG. 7 is a schematic diagram illustrating the first step of making a capacitive touch panel according to a second embodiment of the present disclosure. The first step includes forming on a substrate (not shown), first conductive units 53 in a first axial direction and second conductive units 54 in a second axial direction, and electrically connecting the adjacent first conductive units 53 with each other through first conductive wires 51 in the first axial direction to form first electrodes 52.

FIG. 8 is a schematic diagram illustrating the second step of making the capacitive touch panel according to the second embodiment of the present disclosure. The second step includes forming insulating blocks 56 at each of the first conductive wires 51.

The third step includes electrically connecting adjacent second conductive units 54 through second conductive wires 58 at each insulating block 56 and using the insulating block 56 to insulate the second conductive wires 58 from the first electrodes 52, so that the electrically connected second conductive units 54 and second conductive wires 58 form the second electrode 62. Also, each peripheral circuit 60 disposed on the substrate (not shown) is electrically connected with the first sensing electrodes 52 and the second sensing electrodes 62. Capacitive change produced on the first sensing electrodes 52 and the second sensing electrodes 62 due to touching can be transmitted to a control circuit (not shown) by the peripheral circuits 60. After the aforementioned three steps are completed, structure of the capacitive touch panel 50 as shown in FIG. 6 can be obtained.

In the second embodiment, a plurality of peripheral circuits 60 and second conductive wires 58 are made of a photosensitive material having an electrically conductive property, and therefore the peripheral circuits 60 and second conductive wires 58 also have the advantages of the first embodiment.

The first conductive units, the second conductive units, and the first conductive wires in the capacitive touch panel of each aforementioned embodiment can be made of a transparent conductive material such as indium tin oxide (ITO), and the insulating film or insulating blocks of the insulating layer can be made of a transparent insulating material. Each of the aforementioned components can be made by a conventional photo-etching method or printing method.

Advantage of the present disclosure is to provide structure of a capacitive touch panel, in which the conductive wires and peripheral circuits are made of a photosensitive material having an electrically conductive property. As the photosensitive material has the photosensitive property and the electrically conductive property at the same time, the conductive wires are not liable to be seen by naked eyes while providing a good electrical connection, so that the whole appearance of the touch panel can be coordinated. Also, as the photosensitive material is highly chemically stable, the problem of its being oxidized after exposure to the atmosphere over a long time can be improved. Therefore, the step of making a protective layer on the surface of the touch panel can be omitted.

While the present invention has been described above with reference to the preferred embodiment and illustrative drawings, it should not be considered as limited thereby. Various equivalent alterations, omissions and modifications made to its configuration and the embodiments by the skilled persons could be conceived of without departing from the scope of the present invention.

What is claimed is:

1. A capacitive touch panel, comprising:
sensing electrodes comprising a plurality of conductive units and a plurality of conductive wires for connecting the conductive units, wherein the conductive wires are made of a photosensitive material having an electrically conductive property.

2. The capacitive touch panel according to claim 1, wherein the photosensitive material having the electrically conductive property is a photosensitive material doped with metal particles.

3. The capacitive touch panel according to claim 2, wherein the metal particles comprises of one or more of gold, silver, copper, iron or aluminum, and any combinations thereof.

4. The capacitive touch panel according to claim 1, wherein the photosensitive material having the electrically conductive property is a photosensitive material doped with carbon particles.

5. The capacitive touch panel according to claim 1, wherein the sensing electrodes include first sensing electrodes arranged in a first axial direction and second sensing electrodes arranged in a second axial direction, further wherein an insulating layer is disposed between the first sensing electrodes and the second sensing electrodes.

6. The capacitive touch panel according to claim 5, wherein each of the first sensing electrodes comprises a plurality of first conductive units and a plurality of first conductive wires connecting the first conductive units, and each of the second sensing electrodes comprises a plurality of second conductive units and a plurality of second conductive wires connecting the second conductive units.

7. The capacitive touch panel according to claim 6, wherein the insulating layer is an insulating film having a plurality of openings, wherein the first conductive units, the second conductive units, and the first conductive wires are provided on backside of the insulating film with the plurality of openings aligned with the second conductive units, further wherein the second conductive wires are provided on front side of the insulating film and pass through the plurality of openings to connect the second conductive units.

8. The capacitive touch panel according to claim 6, wherein the insulating layer comprises a plurality of insulating blocks, further wherein the insulating blocks are disposed between the plurality of first conductive wires and the plurality of second conductive wires.

9. The capacitive touch panel according to claim 1, wherein the sensing electrodes are connected to peripheral circuits.

10. The capacitive touch panel according to claim 9, wherein the peripheral circuits and the conductive wires are made of the photosensitive material having an electrically conductive property.

11. A method of manufacturing a capacitive touch panel, comprising the following steps:
disposing a plurality of conductive units on a substrate; and
disposing a plurality of conductive wires, which connect the conductive units to form sensing electrodes, wherein the conductive wires are made of a photosensitive material having an electrically conductive property.

12. The method of manufacturing a capacitive touch panel according to claim 11, wherein the photosensitive material having an electrically conductive property is a photosensitive material doped with metal particles.

13. The method of manufacturing a capacitive touch panel according to claim 11, wherein the metal particles comprise of one or more of gold, silver, copper, iron or aluminum, and any combinations thereof.

14. The method of manufacturing a capacitive touch panel according to claim 11, wherein the photosensitive material having an electrically conductive property is a photosensitive material doped with carbon particles.

15. The method of manufacturing a capacitive touch panel according to claim 11, wherein the sensing electrodes comprise of first sensing electrodes arranged in a first axial direction and second sensing electrodes arranged in a second axial direction, wherein the method further comprises a step of disposing an insulating layer between the first sensing electrodes and the second sensing electrodes.

16. The method of manufacturing a capacitive touch panel according to claim 15, wherein each of the first sensing electrodes comprises a plurality of first conductive units, each of the second sensing electrodes comprises a plurality of second conductive units, further wherein the conductive wires include a plurality of first conductive wires connecting the first conductive units and a plurality of second conductive wires connecting the second conductive units.

17. The method of manufacturing a capacitive touch panel according to claim 16, further comprising the following steps:
simultaneously disposing the first conductive units, the second conductive units, and the first conductive wires on the substrate;
disposing an insulating film having a plurality of openings on surfaces of the first conductive units, the second conductive units, and the first conductive wires such that the openings are aligned with the second conductive units; and
disposing the second conductive wires on surface of the insulating film.

18. The method of manufacturing a capacitive touch panel according to claim 16, further comprising the following the steps:
simultaneously disposing the first conductive units, the second conductive units, and the first conductive wires on the substrate;
disposing insulating blocks on surfaces of the first conductive wires; and
disposing the second conductive wires on surfaces of the insulating blocks.

19. The method of manufacturing a capacitive touch panel according to claim 11, further comprising the step of disposing peripheral circuits connected with the sensing electrodes.

20. The method of manufacturing a capacitive touch panel according to claim 19, wherein the step of disposing the peripheral circuits and the step or disposing a plurality of conductive wires are conducted simultaneously.
